(19) United States
(12) Patent Application Publication
(10) Pub. No.: US 2013/0077282 A1
(43) Pub. Date: Mar. 28, 2013

(54) INTEGRATED THERMAL AND EMI SHIELDS AND METHODS FOR MAKING THE SAME

(71) Applicants: Shayan Malek, San Jose, CA (US); Michael Wittenberg, Sunnyvale, CA (US); Richard Hung Minh Dinh, San Jose, CA (US)

(72) Inventors: Shayan Malek, San Jose, CA (US); Michael Wittenberg, Sunnyvale, CA (US); Richard Hung Minh Dinh, San Jose, CA (US)

(73) Assignee: APPLE INC., Cupertino, CA (US)

(21) Appl. No.: 13/607,567

(22) Filed: Sep. 7, 2012

Related U.S. Application Data
(60) Provisional application No. 61/532,987, filed on Sep. 9, 2011.

(51) Int. Cl. H05K 9/00; H05K 13/04

(52) U.S. Cl. CPC H05K 9/003; H05K 13/04
USPC 361/818; 29/832

(57) ABSTRACT

Electronic devices having integrated thermal and EMI shields for providing thermal dissipation and EMI shielding of one or more circuitry components, and methods for making the same, are provided. The integrated shield combines both thermal and EMI shielding properties into a single layer material that saves space within the electronic device. The integrated shield can be constructed from a silicon material having one or more EMI shielding additives incorporated therein.

### CROSS-REFERENCE TO RELATED APPLICATION

This application claims the benefit of U.S. Provisional Application No. 61/532,987, filed Sep. 9, 2011, the disclosure of which is incorporated by reference herein in its entirety.

### BACKGROUND

This is directed to using an integrated thermal and electromagnetic interference (EMI) shielding for components of an electronic device. In particular, this is directed to an integrated shield constructed from a silicon material having EMI inducing additives incorporated therein.

A portable electronic device can include several components coupled to a circuit board for providing processing and other device operations. Some of the components can generate electromagnetic waves that interfere with the operation of other components of the device. In addition, the components can generate heat that needs to be dissipated. For example, circuitry associated with connecting to a communications network can interfere with other device components (e.g., sensor arrays) and can also generate heat that can be detrimental to the operation of the circuitry. To protect the components from such interference, different approaches can be used. In one approach a conductive can shielding can be constructed around the components and a thermal material can be placed on top of the can or between the can and component.

The approach, however, may require two distinct components, one for providing thermal dissipation and another for providing EMI shielding. This can in turn require additional space within the device for both the thermal component and the EMI shield, which may place a limit on the device size.

### SUMMARY OF THE INVENTION

Electronic devices having integrated thermal and EMI shields for providing thermal dissipation and EMI shielding of one or more circuitry components, and methods for making the same, are provided. The integrated shield combines both thermal and EMI shielding properties into a single layer material that saves space within an electronic device. For example, using a single layer material may save space in the z-height direction. The integrated shield can be constructed from a silicon material having one or more EMI shielding additives incorporated therein. Various different embodiments of such shields are discussed in more detail below.

### BRIEF DESCRIPTION OF THE DRAWINGS

The above and other features of the present invention, its nature and various advantages will be more apparent upon consideration of the following detailed description, taken in conjunction with the accompanying drawings in which:

FIG. 1 is a schematic view of an illustrative electronic device according to an embodiment of the invention;

FIG. 2 shows an illustrative exploded view of electronic device having an integrated thermal and EMI shield according to an embodiment of the invention.

FIG. 3 shows an illustrative cross-sectional view of the electronic device of FIG. 2 according to an embodiment of the invention;

FIG. 4 shows an illustrative exploded view of electronic device having another integrated thermal and EMI shield according to an embodiment of the invention.

FIG. 5 shows an illustrative cross-sectional view of the electronic device of FIG. 4 according to an embodiment of the invention;

FIG. 6 shows an illustrative exploded view of electronic device having yet another integrated thermal and EMI shield according to an embodiment of the invention;

FIG. 7 shows an illustrative cross-sectional view of the electronic device of FIG. 6 according to an embodiment of the invention;

FIG. 8 is a flowchart of an illustrative process for providing an integrated thermal and EMI shield according to an embodiment of the invention; and

FIG. 9 is a flowchart of an illustrative process for providing an integrated thermal and EMI shield according to an embodiment of the invention.

### DETAILED DESCRIPTION

An electronic device can have components for which EMI shielding is required. To provide appropriate EMI shielding while limiting the amount of space required for the shield, the electronic device can include a conformal coating layer constructed from conductive material. The conductive conformal coating can be electrically coupled to one or more pads on a circuit board of the electronic device (e.g., around a periphery of device components) to ensure that the conductive coating, which serves as an EMI shield, is grounded. The electronic device can include an intermediate non-conductive coating between the electronic device components and the conductive conformal coating layer to ensure that the conductive layer does not short the electronic device components. In some embodiments, the non-conductive layer can include openings in the layer to allow the conductive layer to be electrically coupled to the circuit board.

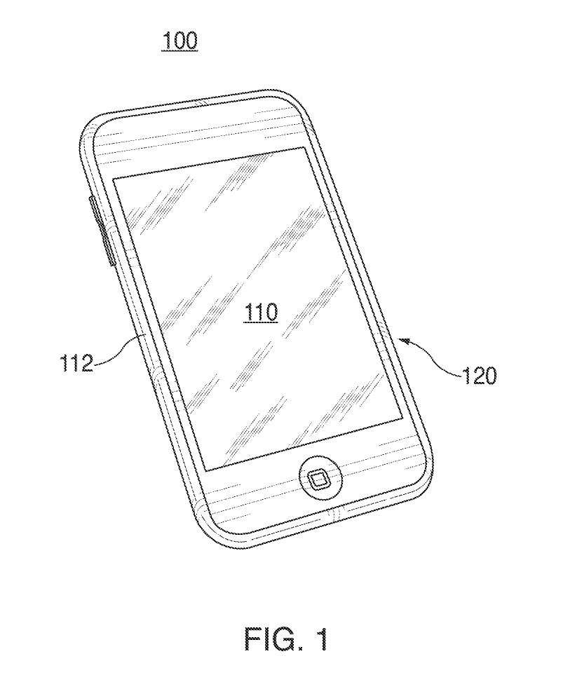

FIG. 1 is a schematic view of an electronic device in accordance with one embodiment of the invention. Electronic device 100 can include front cover 110, bezel 112, and back cover 120. Front and back covers 110 and 120 can be secured to bezel 112. Front cover 110 can be constructed from any suitable material, including for example, plastic or glass. Back cover 120 can also be constructed from any suitable material such as, for example, plastic, glass, metal, or a composite. Bezel 112 can be constructed from plastic or any metal such as aluminum or stainless steel. In one embodiment, front and back covers 110 and 120 can be constructed from any suitable transparent or translucent material, including, for example, glass or plastic, and bezel 112 can be constructed from a metal. Different electronic device components can be retained within electronic device 100 to provide desired functionality to the user. In some embodiments, electronic device 100 can include components that generate electromagnetic waves that may interfere with the proper operation of other electronic device components. These components may also generate heat. These components may then need to be shielded and provided with thermal protection to ensure proper operation of the electronic device.

Embodiments of this invention use an integrated thermal and EMI shield. This integrated shield is a single component that provides both heat dissipation and EMI shielding for any component that generates heat and electromagnetic interference. By combining both heat dissipation and EMI shielding into a single component, space savings can be achieved in at least the z-direction, and depending on the type of grounding structure used (e.g., fence or metal gasket, discussed below), space savings can be achieved in the x and y directions as well.

The integrated shield according to embodiments of the invention can be constructed from a silicon material that has one or more EMI shielding additives incorporated therein. The silicon material may provide the desired thermal property and the EMI shielding additive(s) may provide the desired EMI shielding for the integrated shield. The silicon material can be any suitable silicon based substrate. The EMI shielding additives can include any combination of materials such as metal (e.g., copper, aluminum, nickel, gold, zinc) and/or conductive fillers (e.g., nickel graphite powder or silver conductive filler). For example, in one embodiment, the integrated shield can be constructed from silicon and nickel graphite powder. As another example, the integrated shield can be formed by combining a powder additive made from 55% copper, 27% zinc, and 18% nickel with a silicon base.

The integrated shield can be constructed to take any suitable shape. For example, the integrated shield can have a lid shape in which it has a surface and at least two verticals walls stemming from the surface. In some embodiments, the integrated shield can have four or more vertical walls. The integrated shield can cover one or more circuitry components when secured in position. As will be discussed in more detail below, the manner in which the integrated shield can be secured depends on whether it engages a conductive fence or is directly soldered to a circuit board.

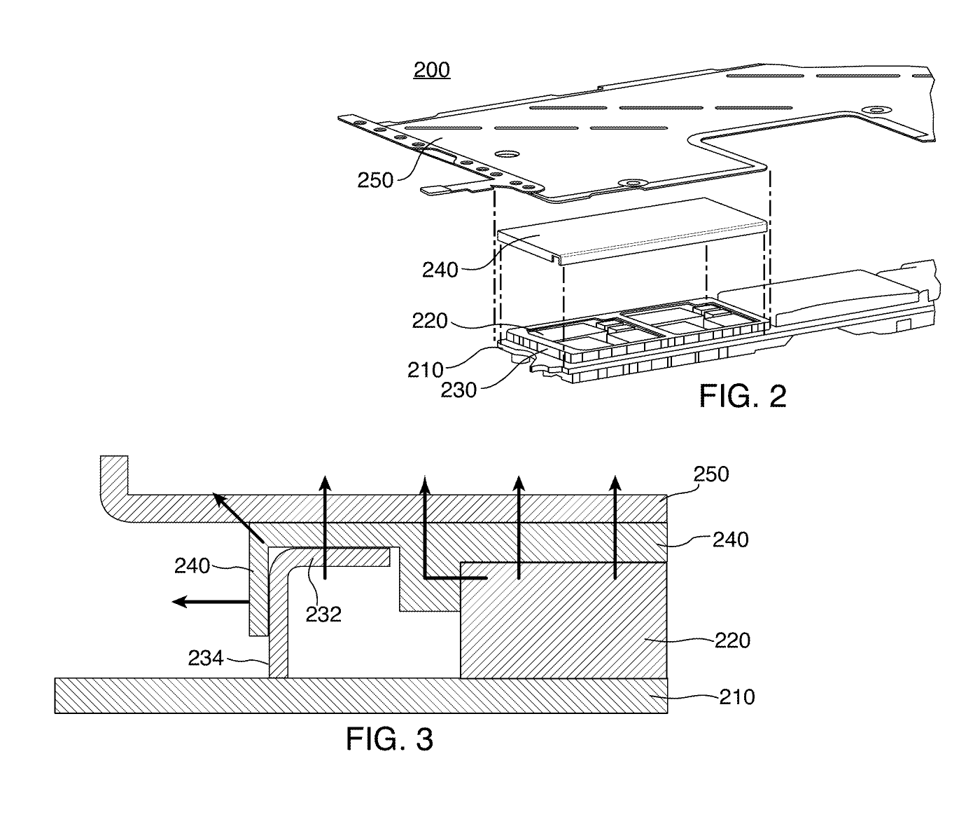

FIG. 2 shows an illustrative exploded view of electronic device 200 having an integrated thermal and EMI shield according to an embodiment of the invention. FIG. 3 shows an illustrative cross-sectional view of electronic device 200. Reference will be made to both FIGS. 2 and 3, below. As shown, electronic device 200 includes circuit board 210, which has components 220 mounted thereon. Components 220 are surrounded by flanged conductive fence 230, which is electrically connected to several ground points around a perimeter of components 220.

Flanged conductive fence 230 includes flanged portion 232 and one or more vertical portions 234. The flanged portion can be a ring or upper boundary member that is aligned with a perimeter wall and enhances the structural integrity of the fence. The vertical portion may stem down from the flanged portion at one or more locations around the flanged portion. The vertical portion can be a continuous, uninterrupted vertical wall, or it can be intermittent.

Electronic device 200 also includes integrated thermal and EMI shield 240. Shield 240 can be constructed to have a lid structure so that the lid portion can engage flanged conductive fence 230. For example, shield 240 can have fence engagement members (not shown) that can be releasably coupled to fence 230. Thus, shield 240 can be removed relatively easily from electronic device 200 for servicing, for example, one or more components 220. Fence engagement members can be, for example, snap fit structures, tabs, or the like. The coupling between shield 240 and fence 230 can complete the ground connection to circuit board 220, thereby enabling shield 240 to provide EMI shielding.

Shield 240 can be constructed to sit on top of and/or partially around one or more components 220. Such direct contact between shield 240 and components 220 promotes thermal dissipation. In some embodiments, shield 240 can have a contoured inner surface that accommodates various height differences among components 220.

Electronic device 200 can also include structure 250 that may be secured directly on top of shield 240. Structure 250 can be any suitable object that has a substantially planer surface such as a battery, display, or board support structure. When structure 250 is secured within device 200, it may fit flush against shield 240 such that no gap exists at the interface between structure 250 and shield 240. A gapless interface may exist since the silicon component of shield 240 may provide compliance and may be able to accommodate variations in the surface of structure 250.

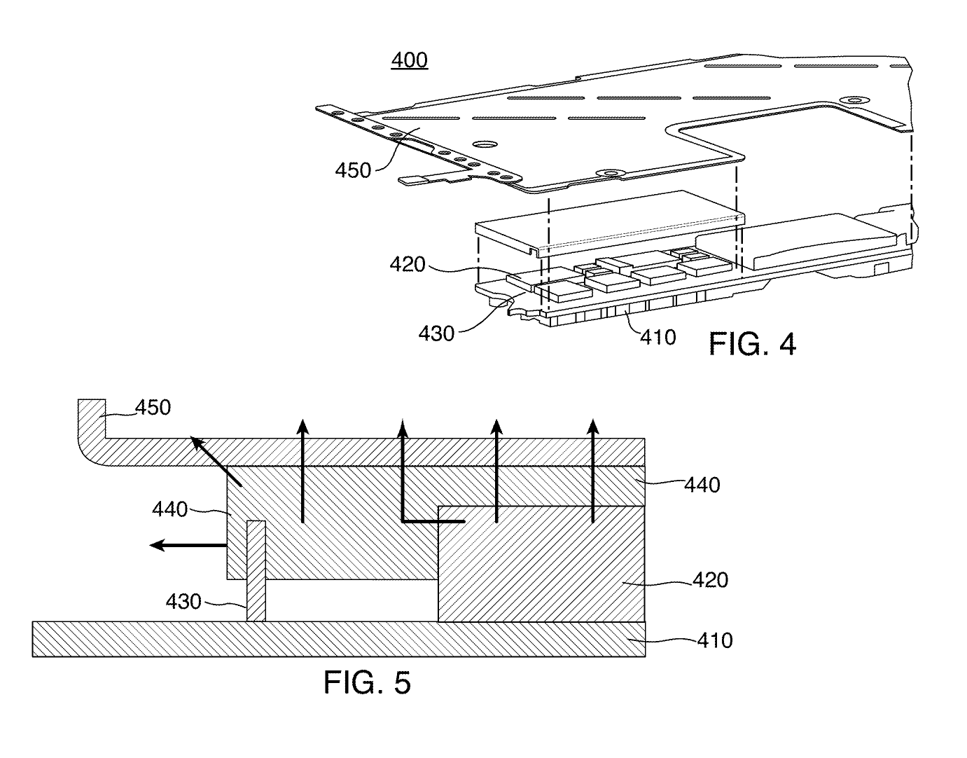

FIG. 4 shows an illustrative exploded view of electronic device 400 having an integrated thermal and EMI shield according to an embodiment of the invention. FIG. 5 shows an illustrative cross-sectional view of electronic device 500. As shown, electronic device 400 includes many of the same features as that discussed above in connection with electronic device 200 (of FIGS. 2 and 3) with the differences being in the configuration of fence 430 and shield 440. Electronic device 400 can include circuit board 410, components 420, conductive flangeless fence 430, integrated thermal and EMI shield 440, and structure 450.

Conductive flangeless fence 430 may be physically and electrically coupled to circuit board 410. Flangeless fence 430 does not have any flange portion such as that shown in flanged fence 230 of FIG. 2 or any curved overhanging structure. Instead, flangeless fence 430 may have a continuous vertical wall portion that provides an uninterrupted top line along the fence's periphery. While the top portion of the vertical wall is continuous, the bottom portion of the vertical wall can be either continuous or intermittent. The vertical wall construction of shield 440 provides more available board space in the x and y dimensions than shield 240 of FIG. 2.

Shield 440 can be constructed to have a lid with integrated fence retaining members (not shown) for enabling shield 440 to be removeably coupled to fence 430. When shield 440 is coupled to fence 430, it may be electrically coupled to board 410 and provide EMI shielding for components 440. In addition, when shield 440 is secured within electronic device 400, it can interface flush with components 420 in the same or similar manner as the component/shield interface discussed above in connection with FIG. 3.

Structure 450 can be secured on top of shield 440. The interface between shield 440 and structure 450 can be gapless. A gapless interface may exist since the silicon component of shield 440 may provide compliance and may be able to accommodate variations in the surface of structure 450. Direct contact between shield 440 and structure 450 may promote thermal dissipation.

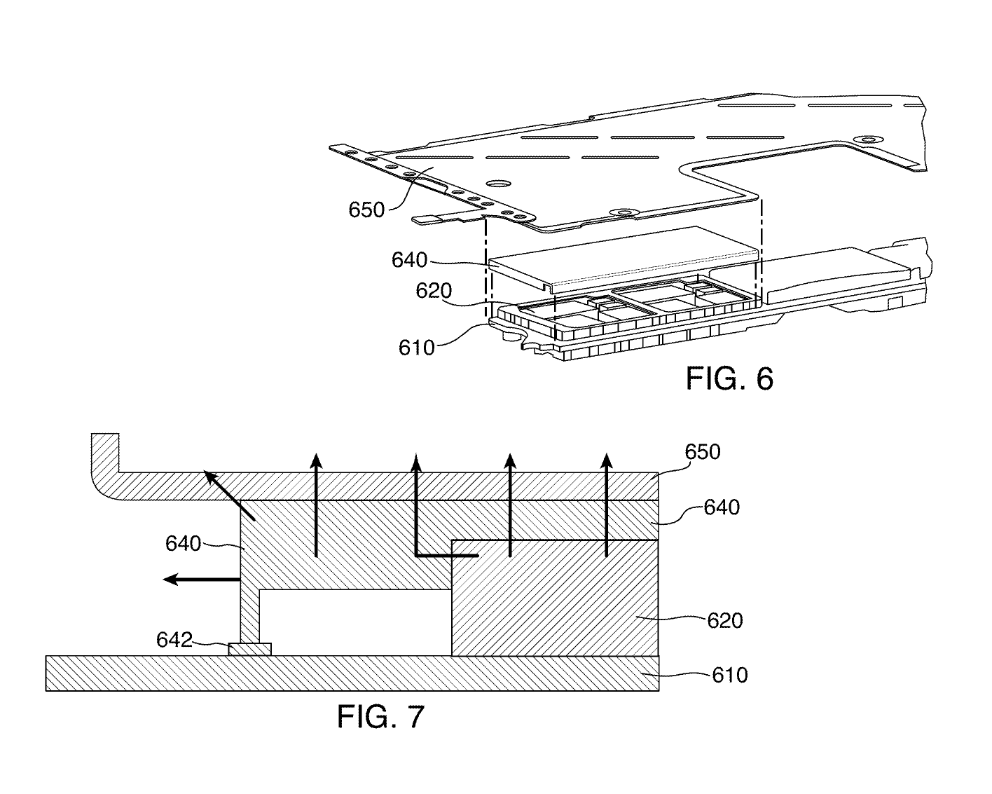

FIG. 6 shows an illustrative exploded view of electronic device 600 having an integrated thermal and EMI shield according to an embodiment of the invention. FIG. 7 shows an illustrative cross-sectional view of electronic device 600. Electronic device 600 includes circuit board 610, components 620, integrated thermal and EMI shield 640, and structure 650. Electronic device 600 may include many of the same features as devices 200 and 400 of FIGS. 2 and 4, respectively. As a result, similarly numbered features of electronic device 600 may share any characteristics described with respect to devices 200 and 400, and vice versa.

Shield 640 can have a lid structure that has integrated metal gasket 642. Metal gasket 642 may be integrated with shield 640 using any suitable method. For example, metal gasket 642 can be insert molded to shield 640. In addition, metal gasket 642 may be shaped to have a rectangular foot structure so that it supports itself on circuit board 610. In addition, the foot structure may be amenable to being soldered to circuit board 610. When shield 640 is physically and electrically coupled to circuit board 610, it may provide both thermal dissipation and EMI shielding for components 620.

Shield 640 may sit flush against at least the top surface of one or more components 620 to provide thermal dissipation. In some embodiments, shield 640 can sit flush against the sides of one or more components 620. A gapless interface may exist between shield 640 and structure 650.

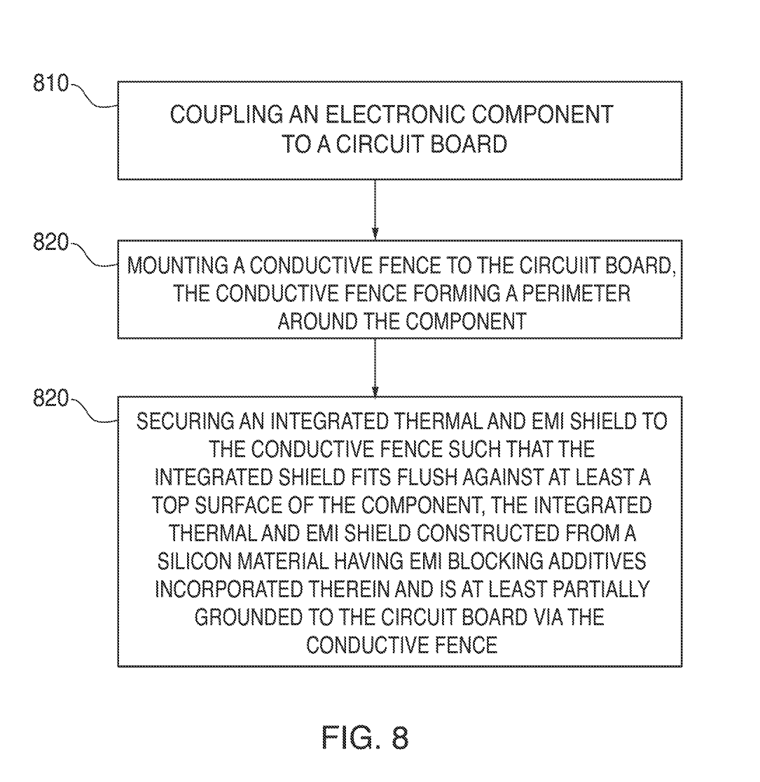

FIG. 8 is a flowchart of an illustrative process for providing an integrated thermal and EMI shield in accordance with one embodiment of the invention. Beginning at step 810, an electronic component is coupled to a circuit board. At step 820, a conductive fence is mounted to the circuit board, the conductive fence forming a perimeter around the component. For example, a flanged fence or a flangeless fence can be mounted to the circuit board. Then, at step 830, an integrated thermal and EMI shield may be secured to the conductive fence such that the integrated shield fits flush against at least a top surface of the component, the integrated thermal and EMI shield constructed from a silicon material having EMI blocking additives incorporated therein and is at least partially grounded to the circuit board via the conductive fence.

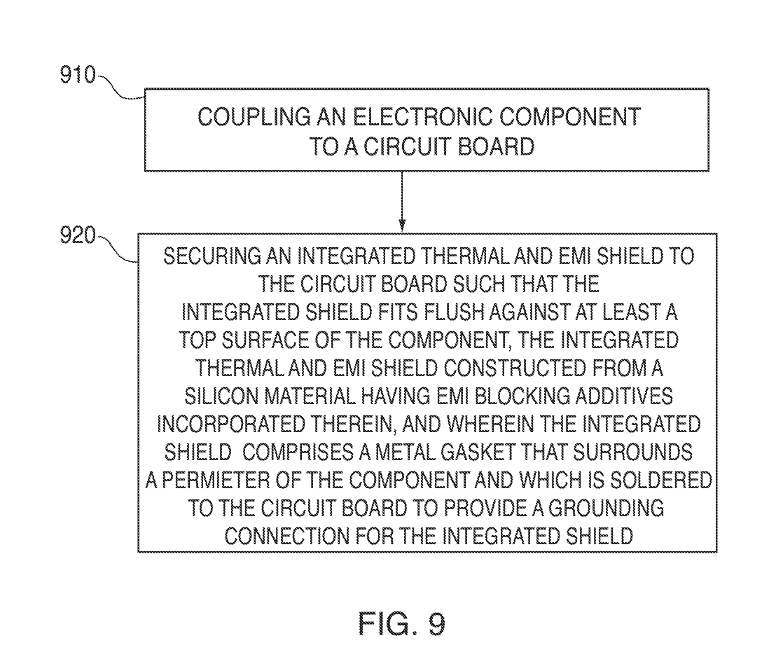

FIG. 9 is a flowchart of an illustrative process for providing an integrated thermal and EMI shield in accordance with one embodiment of the invention. Beginning at step 910, an electronic component is coupled to a circuit board. Then, at step 920, an integrated thermal and EMI shield is integrated to the circuit board such that the integrated shield fits flush against at least a top surface of the component, the integrated thermal and EMI shield constructed from a silicon material having EMI blocking additives incorporated therein, and wherein the integrated shield comprises a metal gasket that surrounds a perimeter of the component and which is soldered to the circuit board to provide a grounding connection for the integrated shield.

The previously described embodiments are presented for purposes of illustration and not of limitation. It is understood that one or more features of an embodiment can be combined with one or more features of another embodiment to provide systems and/or methods without deviating from the spirit and scope of the invention. The present invention is limited only by the claims which follow.

What is claimed is:

1. An electronic device, comprising:
a circuit board;
at least one component coupled to the circuit board, the at least one component requiring EMI and thermal shielding;
a conductive fence disposed on the circuit board and around a periphery of the at least one component; and
an integrated thermal and EMI shield mated to the conductive fence, the integrated thermal and EMI shield constructed from a silicon material having EMI blocking additives incorporated therein and is at least partially grounded to the circuit board via the shield engagement member.

2. The electronic device of claim 1, wherein:
the integrated thermal and EMI shield includes a top surface and a bottom surface, and wherein a portion of the bottom surface interfaces with the at least one component.

3. The electronic device of claim 2, further comprising:
a structure having a first surface that interfaces with the top surface of the integrated thermal and EMI shield.

4. The electronic device of claim 2, wherein substantially no gap exists at the interface between the first and top surfaces.

5. The electronic device of claim 1, wherein:
the at least one component comprises a plurality of sides; and
the integrated thermal and EMI shield is partially grounded to the circuit board along at least two of the plurality of sides.

6. The electronic device of claim 5, wherein:
the integrated thermal and EMI shield is grounded to the circuit board along each of the plurality of sides of the component.

7. The electronic device of claim 1, wherein:
the conductive fence comprises a flangeless fence.

8. The electronic device of claim 1, wherein:
the conductive fence comprises a flanged fence.

9. The electronic device of claim 1, wherein:
the integrated thermal and EMI shield comprises: silicon and a conductive powder.

10. A method for thermally shielding an electronic device component and for shielding the electronic device component from electromagnetic interference, comprising:
coupling the component to a circuit board; and
mounting a conductive fence to the circuit board, the conductive fence forming a perimeter around the component; and
securing an integrated thermal and EMI shield to the conductive fence such that the integrated shield fits flush against at least a top surface of the component, the integrated thermal and EMI shield constructed from a silicon material having EMI blocking additives incorporated therein and is at least partially grounded to the circuit board via the conductive fence.

11. The method of claim 10, wherein:
mounting the conductive fence comprises soldering the conductive fence to the circuit board.

12. The method of claim 10, wherein the conductive fence comprises a plurality of shield retaining members and the integrated shield comprises a plurality of fence engaging members, and wherein securing the integrated shield to the conductive fence comprises interfacing each of the plurality of fence engaging members to respective ones of the plurality of fence engaging members.

13. The method of claim 10, wherein:
the integrated shield comprises silicon and nickel covered graphite.

14. A method for thermally shielding an electronic device component and for shielding the electronic device component from electromagnetic interference, comprising:
coupling the component to a circuit board; and
securing an integrated thermal and EMI shield to the circuit board such that the integrated shield fits flush against at least a top surface of the component, the integrated thermal and EMI shield constructed from a silicon material having EMI blocking additives incorporated therein, and wherein the integrated shield comprises a metal gasket that surrounds a perimeter of the component and which is soldered to the circuit board to provide a grounding connection for the integrated shield.

15. The method of claim 14, wherein the integrated shield comprises silicon and a conductive filler.

16. An electronic device, comprising:
a circuit board;
at least one component coupled to the circuit board, the at least one component requiring EMI and thermal shielding;
a grounding perimeter disposed on the circuit board and around a periphery of the at least one component; and
an integrated thermal and EMI shield comprising a metal gasket that is mounted to the grounding perimeter, the integrated thermal and EMI shield constructed from a silicon material having EMI blocking additives incorporated therein and is at least partially grounded to the circuit board via the metal gasket.

17. The electronic device of claim 16, wherein the metal gasket is insert molded to the integrated thermal and EMI shield.

18. The electronic device of claim 16, wherein:
the metal gasket is soldered to the grounding perimeter.

19. The electronic device of claim 16, further comprising a structure having a first surface that interfaces with a top surface of the integrated thermal and EMI shield.

20. The electronic device of claim 19, wherein substantially no gap exists at the interface between the first and top surfaces.

21. The electronic device of claim 16, wherein:
the EMI additive is a nickel covered graphite.

22. The electronic device of claim 16, wherein the EMI additive is a conductive powder.
